(19) United States
(12) Patent Application Publication
(10) Pub. No.: US 2026/0206300 A1
(43) Pub. Date: Jul. 16, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Pei Shan LEE, Hsinchu (TW); Sheng-Syun WONG, Hsinchu (TW)

(21) Appl. No.: 19/216,747

(22) Filed: May 23, 2025

Related U.S. Application Data
(60) Provisional application No. 63/745,359, filed on Jan. 15, 2025.

(51) Int. Cl. H10D 84/83; H01L 21/311; H10D 30/00; H10D 30/01; H10D 30/43; H10D 62/10; H10D 62/60; H10D 84/01

(52) U.S. Cl. CPC H10D 84/832; H10D 30/014; H10D 30/0191; H10D 30/43; H10D 30/502; H10D 62/102; H10D 62/115; H10D 62/121; H10D 62/60; H10D 84/013; H10P 50/283

(57) ABSTRACT

Embodiments of the present disclosure provide semiconductor device structures and methods of forming the same. The method includes forming a fin structure, and the fin structure includes a first semiconductor layer disposed over a substrate portion. The method further includes removing a portion of the first semiconductor layer to expose a top surface of the substrate portion, a side surface of the substrate portion, and a side surface of the first semiconductor layer, forming a first oxide layer on the exposed top surface of the substrate portion, a second oxide layer on the exposed side surface of the substrate portion, and a third oxide layer on the exposed side surface of the first semiconductor layer, and performing a high-pressure cyclic etching process to remove the first oxide layer. The method further includes forming second semiconductor layer on the top surface of the substrate portion and removing the third oxide layer.

### CROSS-REFERENCE TO RELATED APPLICATIONS

This application claims priority to U.S. Provisional Application Ser. No. 63/746,359 filed on Jan. 15, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 are perspective views of various stages of manufacturing a semiconductor device structure, in accordance with some embodiments.

FIGS. 9A, 10A, 11A, 12A, 13A, 14A, and 15A are cross-sectional side views of various stages of manufacturing the semiconductor device structure taken along the line A-A of FIG. 8, in accordance with some embodiments.

FIGS. 9B, 10B, 11B, 12B, 13B, 14B, and 15B are cross-sectional side views of various stages of manufacturing the semiconductor device structure taken along the line B-B of FIG. 8, in accordance with some embodiments.

FIGS. 16 and 17 are cross-sectional side views of various stages of manufacturing the semiconductor device structure taken along the line B-B of FIG. 8, in accordance with some embodiments.

FIGS. 18, 19, 20, and 21 are cross-sectional side views of various stages of manufacturing the semiconductor device structure taken along the line B-B of FIG. 8, in accordance with alternative embodiments.

FIGS. 22 and 23 are cross-sectional side views of various stages of manufacturing the semiconductor device structure taken along the line B-B of FIG. 8, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

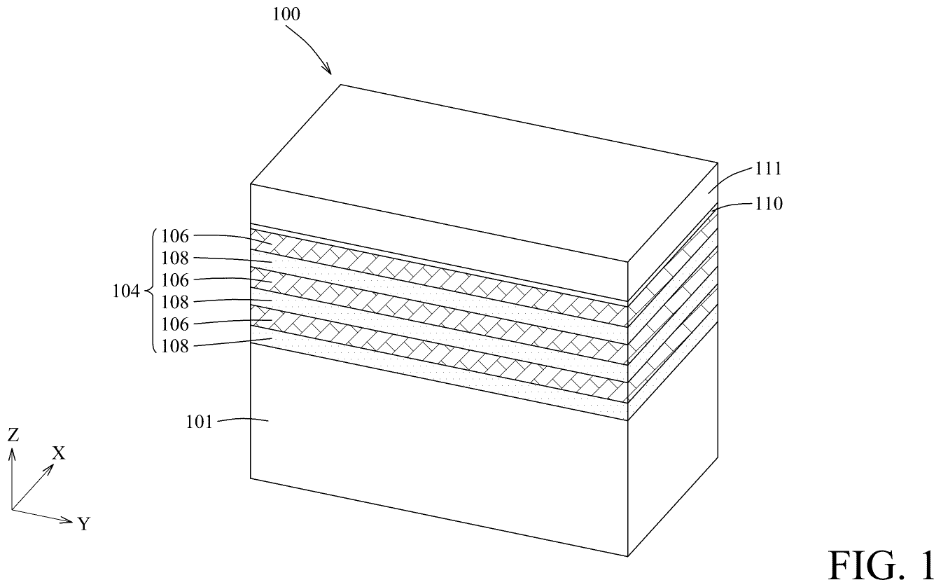

FIGS. 1 to 17 show exemplary processes for manufacturing a semiconductor device structure 100 according to embodiments of the present disclosure. It is understood that additional operations can be provided before, during, and after processes shown by FIGS. 1 to 17, and some of the operations described below can be replaced or eliminated, for additional embodiments of the method. The order of the operations/processes is not limiting and may be interchangeable.

FIGS. 1 to 8 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

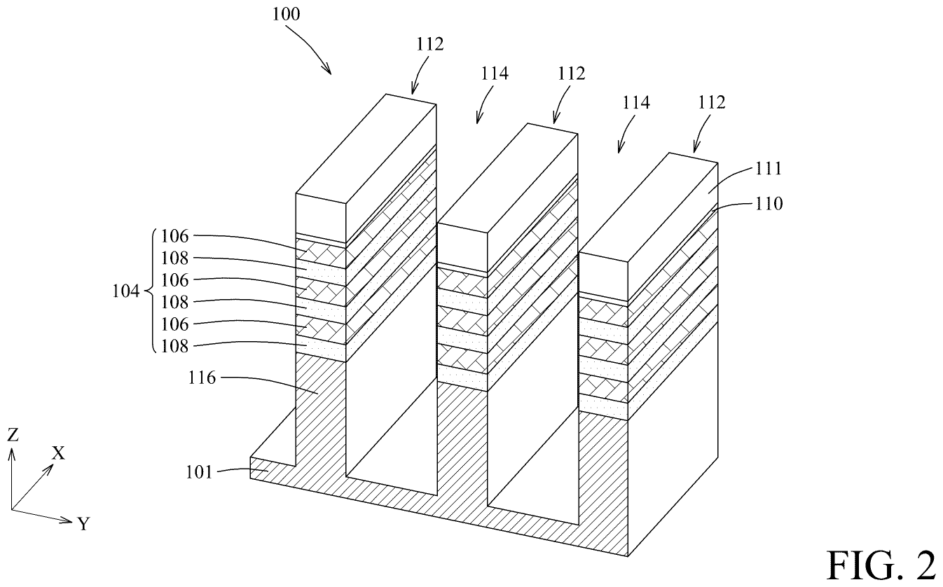

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

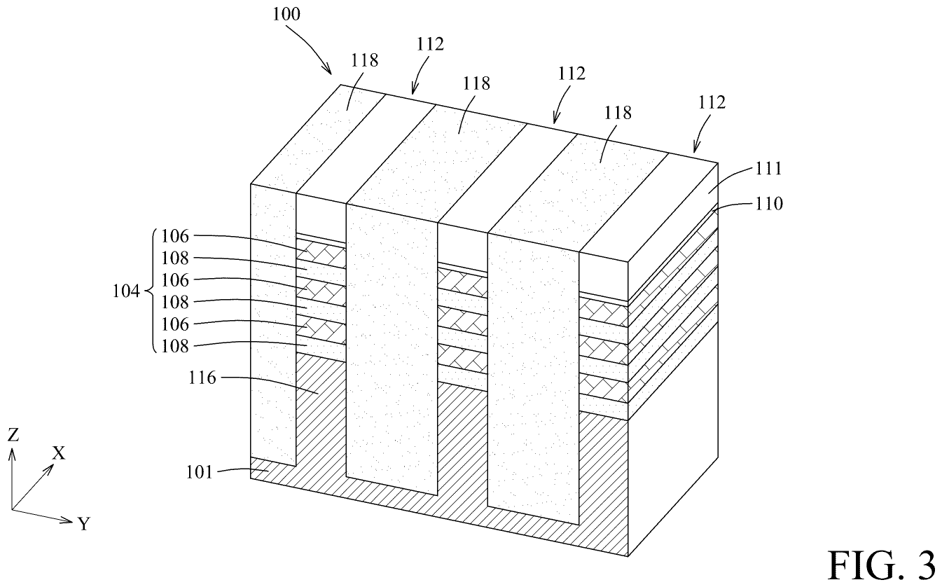

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

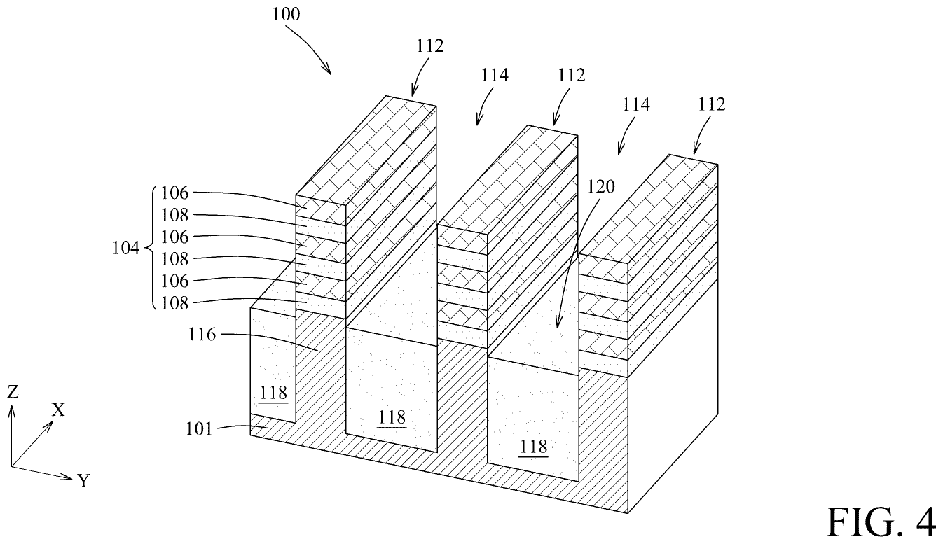

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

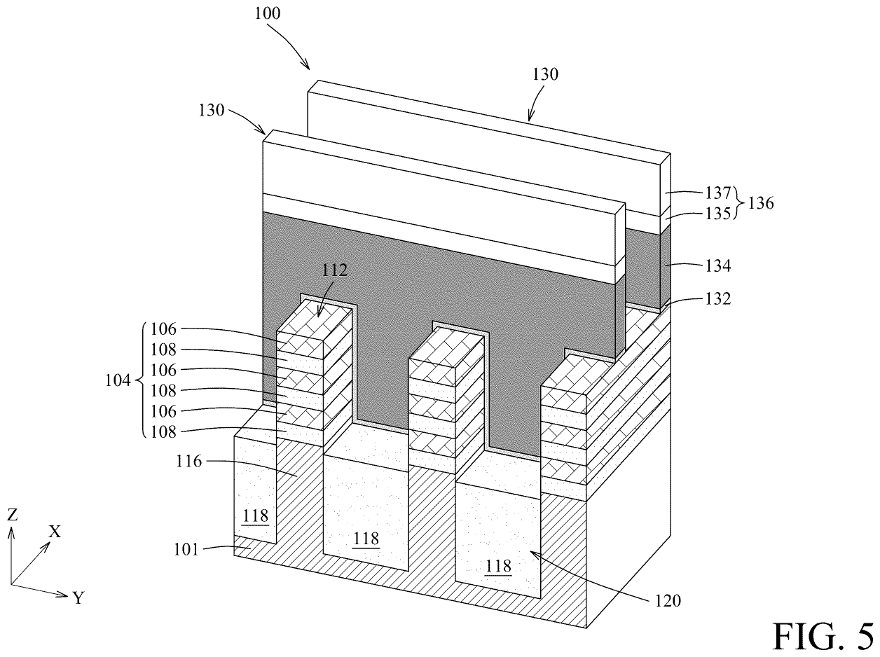

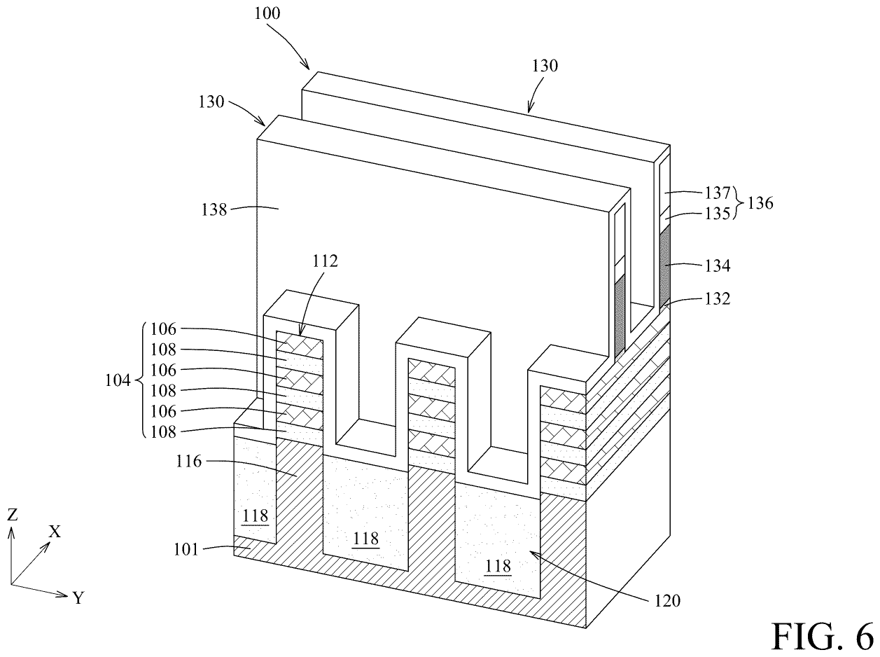

In FIG. 6, a spacer layer 138 is formed to cover the sacrificial gate structures 130, the second portions of the fin structures 112, and the second portions of the isolation regions 120. The spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the spacer layer 138 is formed by a conformal process, such as an atomic layer deposition (ALD) process.

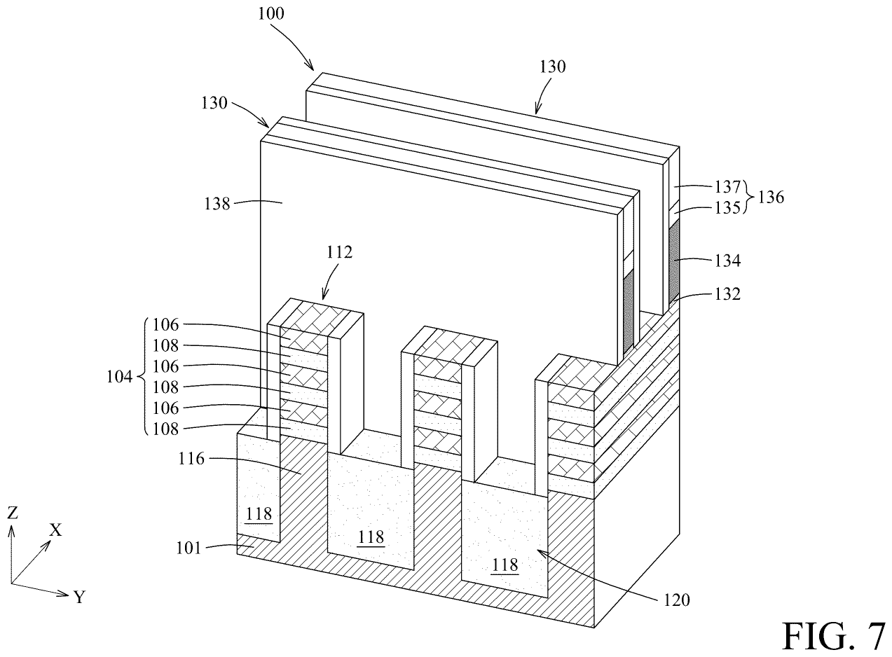

In FIG. 7, an anisotropic etch process is performed to remove horizontal portions of the spacer layer 138. The anisotropic etch process may be a selective etch process that does not substantially affect the nitride layer 137, the first semiconductor layer 106, and the isolation region 120. As a result, the second portions of the fin structures 112 are exposed.

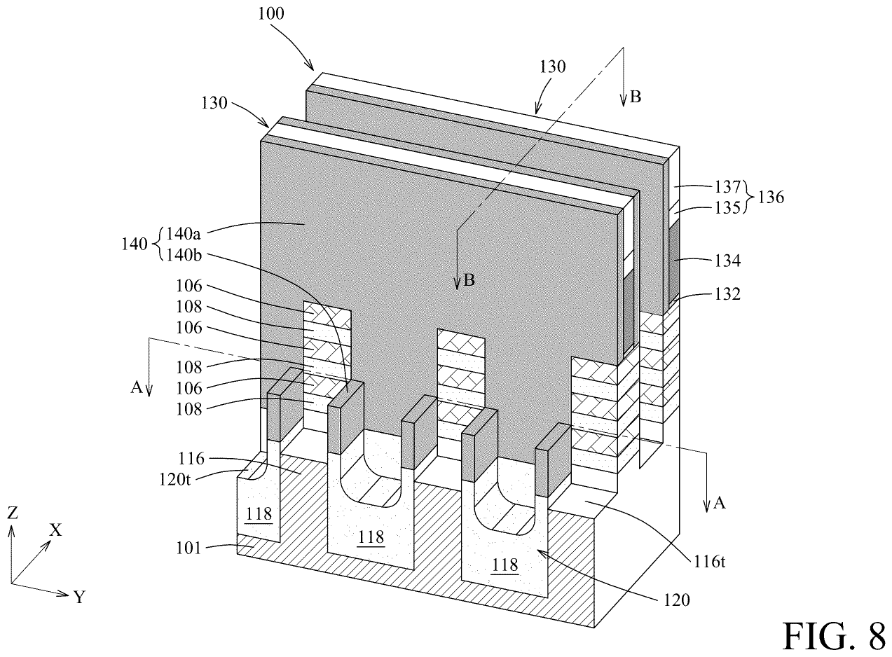

In FIG. 8, one or more etch processes are performed to recess the exposed second portions of the fin structures 112 not covered by the sacrificial gate structures 130 (and the portions of the spacer layer 138 formed on sidewalls of the sacrificial gate structures 130) and to remove portions of the spacer layer 138. The portions of the spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form spacers 140 including a first portion 140a formed on sidewalls of the sacrificial gate electrode layer 134 and second portions 140b formed on the second portions of the isolation regions 120. In some embodiments, the one or more etch processes also remove portions of the second portions of the isolation regions 120, as shown in FIG. 8. As a result, the top surface 120t of the second portion of the isolation region 120 is located at a level substantially below the top surface 116t of the substrate portion 116.

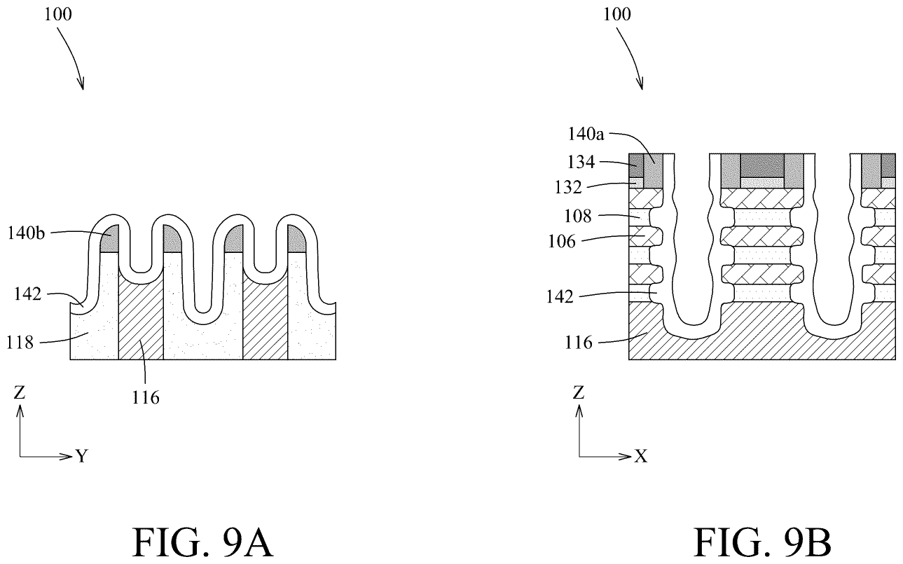

FIGS. 9A, 10A, 11A, 12A, 13A, 14A, and 15A are cross-sectional side views of the semiconductor device structure 100 taken along the line A-A of FIG. 8, in accordance with some embodiments. FIGS. 9B, 10B, 11B, 12B, 13B, 14B, and 15B are cross-sectional side views of the semiconductor device structure 100 taken along the line B-B of FIG. 8, in accordance with some embodiments. The mask layer 136 is omitted in FIGS. 9B-15B for clarity. As shown in FIGS. 9A and 9B, edge portions of each second semiconductor layer 108 of the stack of semiconductor layers 104 are removed horizontally along the X direction. The removal of the edge portions of the second semiconductor layers 108 forms cavities. In some embodiments, the edge portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

In some embodiments, instead of laterally recessing the second semiconductor layers 108, the entire second semiconductor layers 108 are removed to create openings between vertically adjacent first semiconductor layers 106. A dielectric layer (not shown) is formed in the openings between the vertically adjacent first semiconductor layers 106, and the dielectric layer is laterally recessed to form cavities.

After removing edge portions of each second semiconductor layers 108 (or the edge portions of the dielectric layer), a dielectric layer 142 is deposited on the semiconductor device structure 100, as shown in FIGS. 9A and 9B. The dielectric layer 142 may be formed in the cavities, as shown in FIG. 9B. The dielectric layer 142 may be made of a low-K dielectric material, such as SiON, SiCN, SiOC, SiOCN, or SiN. The dielectric layer 142 may be deposited by any suitable process, such as CVD, PECVD, or ALD. In some embodiments, the dielectric layer 142 is a conformal layer formed by a conformal deposition process, such as ALD.

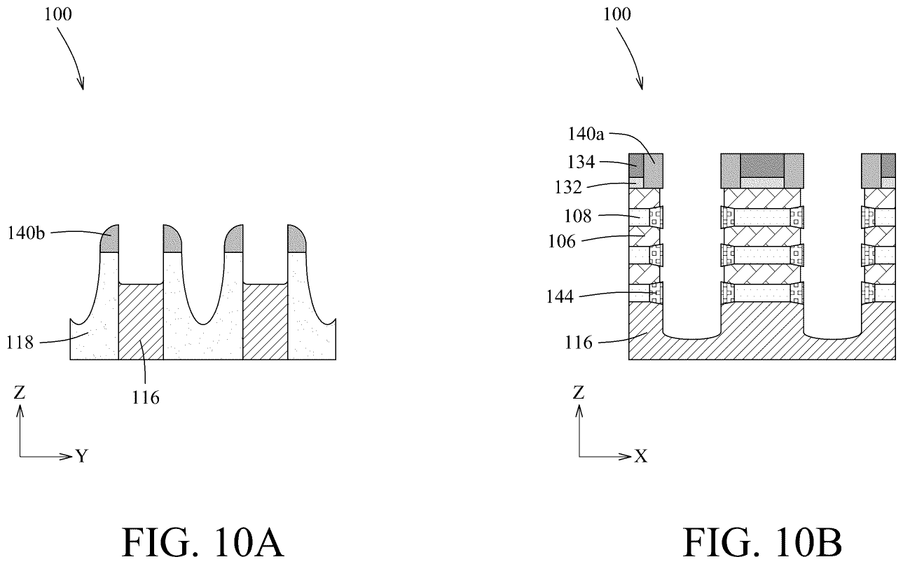

As shown in FIGS. 10A and 10B, an anisotropic etching process is performed to remove portions of the dielectric layer 142 other than portions formed in the cavities, which are now dielectric spacers 144. The dielectric spacers 144 are protected by the first semiconductor layers 106 during the anisotropic etching process. The remaining second semiconductor layers 108 are capped between the dielectric spacers 144 along the X direction.

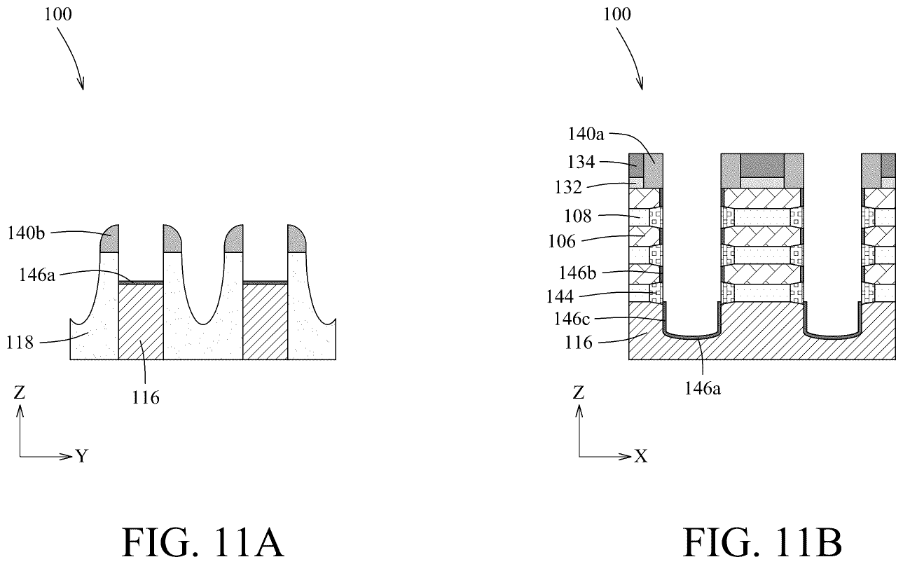

In some embodiments, after the formation of the dielectric spacers 144, the semiconductor device structure 100 is transferred to a different processing equipment for subsequent processing, and oxidation of semiconductor materials of the semiconductor device structure 100 may occur as a result of exposure to the atmosphere. As shown in FIGS. 11A and 11B, in some embodiments, oxide layers 146a, 146b, 146c, 146d are formed on the exposed semiconductor materials. For example, the oxide layers 146a are formed on the exposed top surfaces of the substrate portions 116, the oxide layers 146b are formed on the exposed side surfaces of the first semiconductor layers 106, and the oxide layers 146c are formed on the exposed side surfaces of the substrate portions 116, as shown in FIGS. 11A and 11B. In some embodiments, the oxide layers 146a, 146b, 146c include silicon oxide.

At least some of the oxide layers 146a, 146b, 146c may prevent the formation of source/drain (S/D) regions during subsequent S/D regions formation process. Thus, in some embodiments, the oxide layers 146a, 146b, 146c are removed by multiple etch processes. For example, in some embodiments, the oxide layers 146a and 146c are removed by a high-pressure cyclic etching process. The high-pressure cyclic etching process includes performing multiple cycles, and each cycle includes an etchant generation stage, etching stage, and sublimation stage. The etchant generation stage may include flowing one or more gases into a processing chamber, and reacting the gases at an elevated processing temperature to generate an etchant. The etching stage may include reacting the etchant with the oxide layers 146a, 146c to form a solid product. The sublimation stage may include increasing the processing temperature to sublime the solid product. The one or more gases may include any suitable gases. In some embodiments, the one or more gases are etchant and there is no need to react the gases to form the etchant. In some embodiments, the one or more gases include HF and NH₃, and the elevated processing temperature ranges from about 40 degrees Celsius to about 90 degrees Celsius, such as from about 50 degrees Celsius to about 80 degrees Celsius, for example 60 degrees Celsius. HF and NH₃ may react at the elevated temperature to form NH₄F, which may further react with HF to form NH₄F·HF. Next, at the etching stage, NH₄F·HF and HF react with the materials of the oxide layers 146a, 146c (e.g., SiO₂ in some embodiments) to form a solid product (NH₄)₂SiF₆ and water (H₂O). Next, at the sublimation stage, the processing temperature is further increased to greater than 100 degrees Celsius, at which the solid product and water are being sublimed. In some embodiments, the high-pressure cyclic etching process is a selective etching process that does not substantially affect the dielectric spacers 144, the spacers 140, and the mask layer 136 (FIG. 8).

The one or more gases may continuously flow into the processing chamber during the etchant generation stage and the etching stage. At the end of the etching stage, the one or more gases may be stopped from flowing into the processing chamber in order to control the etching of the oxide layers 146a, 146c. In other words, the one or more gases stop flowing into the processing chamber as the processing temperature starts to increase (to reach the processing temperature for the sublimation stage).

The cycle may be repeated multiple times to remove the oxide layers 146a, 146c. In some embodiments, a purging process may be performed between cycles to purge out the gases formed from the sublimation of the solid product. In some embodiments, during the purging process, the processing temperature is lowered from over 100 degrees Celsius (processing temperature during the sublimation stage) to the processing temperature of the etchant generation stage. An inert gas, such as Ar or N₂, may be flowed into the processing chamber. The one or more gases are not flowed into the processing chamber during the purging process.

In some embodiments, the insulating material 118 is also made of an oxide. Thus, in order to avoid removing the portions of the insulating material 118 formed on the side surfaces of the substrate portion 116, the cyclic etching process is performed at a high processing pressure. In some embodiments, the pressure inside of the processing chamber in which the cyclic etching process is performed is greater than about 7 Torr, such as from about 7 Torr to about 20 Torr, for example from about 15 Torr to about 20 Torr. At such high processing pressure, the etching process is anisotropic. As a result, the portions of the insulating material 118 formed on the side surfaces of the substrate portion 116 are not etched by the cyclic etching process. In some embodiments, the high processing pressure may be maintained during the entire cyclic etching process.

In some embodiments, the time duration of each cycle is short, such as from about 20 seconds to about 30 seconds, in order to further reduce the risk of removing the portions of the insulating material 118 formed on the side surfaces of the substrate portions 116. The number of cycles may range from about three to about five. The number of cycles may be based on the thickness of the oxide layers 146a, 146c. Thicker oxide layers 146a, 146c may lead to more cycles, while thinner oxide layers 146a, 146c may lead to less cycles. The thickness of the oxide layers 146a, 146c may depend on the how long the semiconductor device structure 100 is exposed to the atmosphere.

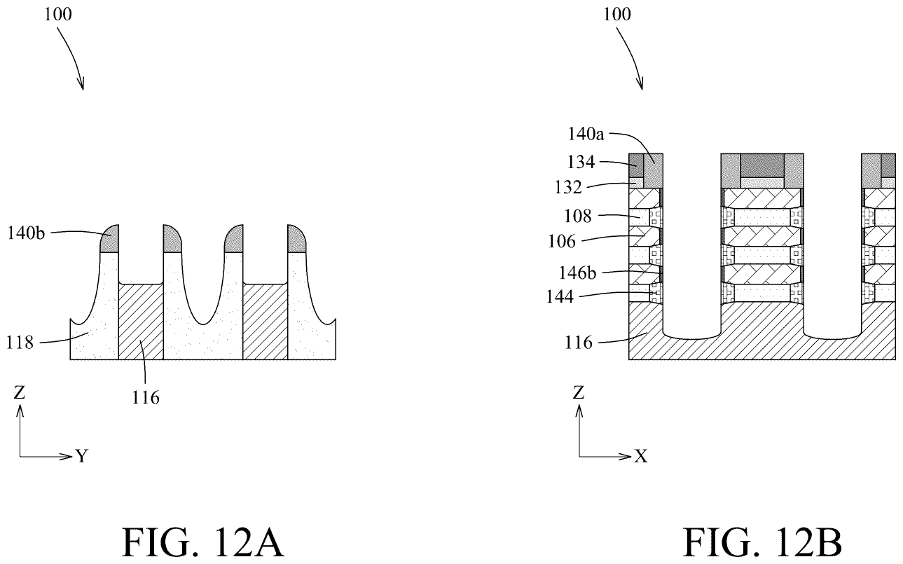

As shown in FIGS. 12A and 12B, the oxide layers 146a formed on the top surface of the substrate portion 116 are removed by the high-pressure cyclic etching process. In some embodiments, the oxide layers 146c formed on the side surfaces of the substrate portions 116 are also removed by the high-pressure cyclic etching process, because the oxide layers 146c are located near a bottom of a trench, as shown in FIG. 11B. In some embodiments, the oxide layers 146b formed on the exposed side surfaces of the first semiconductor layers 106 are not removed by the cyclic etching process. Because the high-pressure cyclic etching process is an anisotropic etching process, the oxide layers 146b may be protected by the first portion 140a of the spacer 140 and dielectric spacers 144 during the anisotropic etching process.

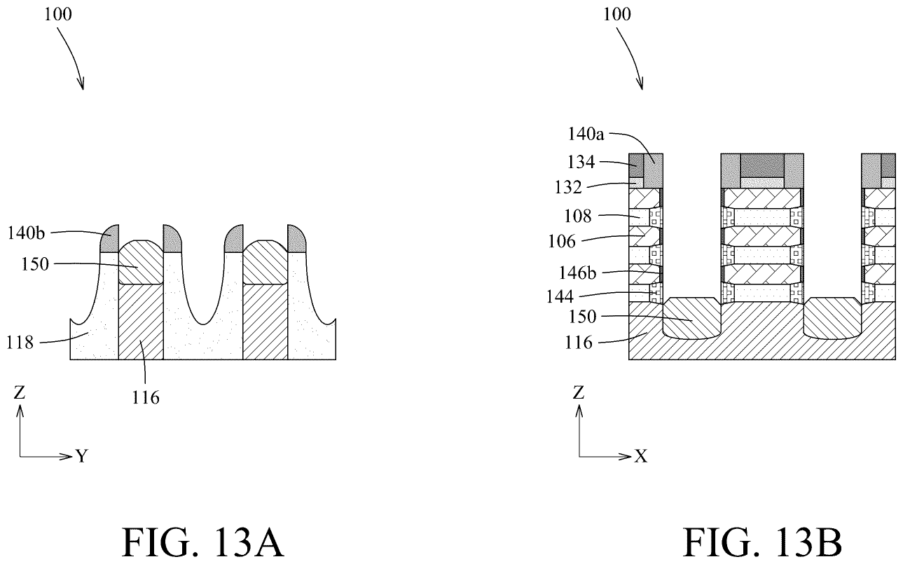

As shown in FIGS. 13A and 13B, an interposing layer 150 is formed on the exposed top surface of the substrate portion 116. The interposing layer 150 may be formed in a processing chamber connected to the processing chamber in which the cyclic etching process is performed. Thus, the transfer of the semiconductor device structure 100 would not expose the semiconductor device structure 100 to the atmosphere. The interposing layer 150 may be a semiconductor layer, a dielectric layer, or a combination thereof. In some embodiments, the interposing layer 150 includes undoped silicon or undoped SiGe. In some embodiments, the term undoped may include materials being unintentionally doped. For example, the interposing layer 150 may contain dopant diffused from other regions. The interposing layer 150 may function as an isolation to prevent leakage from the S/D regions to the substrate portion 116. In some embodiments, the interposing layer 150 may be formed using an epitaxial process that grows the interposing layer 150 on a semiconductor material. Thus, in some embodiments, the oxide layers 146b prevent the formation of the interposing layer 150 on the first semiconductor layers 106. If the interposing layer 150 is formed on the first semiconductor layer 106, the electrical resistance between the S/D region and the channel region would be increased.

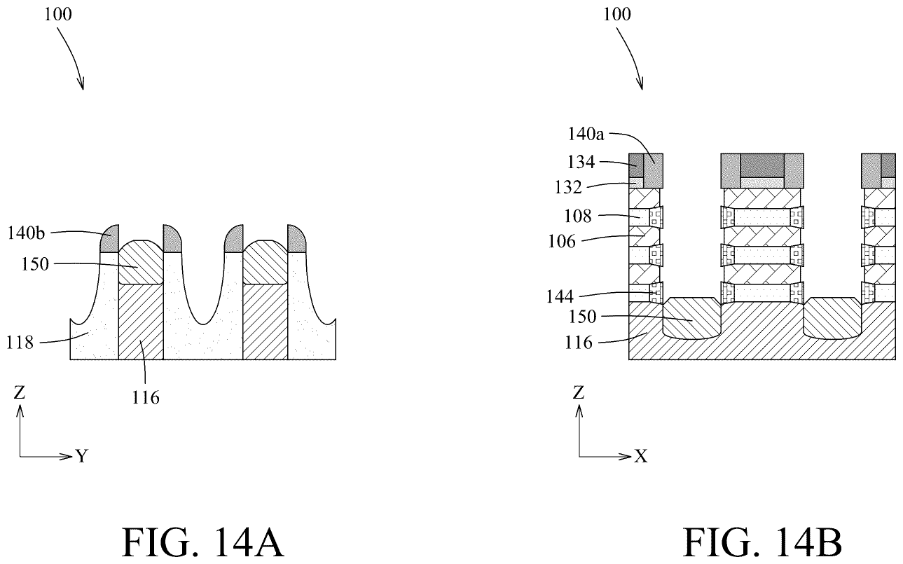

As shown in FIGS. 14A and 14B, a clean process is performed to remove the oxide layers 146b. The clean process may be an isotropic etching process. The time duration of the clean process may be short to prevent removing the portions of the insulating material 118 formed on the side surfaces of the substrate portions 116. Furthermore, the oxide layers 146b are at locations higher than the insulating material 118, and the clean process may be controlled so the etchant does not reach the bottom of the trench shown in FIG. 14B. Some examples of how to prevent the etchant from reaching the bottom of the trench may include increasing the flow rate of the etchant and/or decreasing the processing pressure. In some embodiments, the processing pressure of the clean process is substantially lower than the processing pressure of the high-pressure cyclic etching process. In some embodiments, the clean process is a selective etching process that does not substantially affect the dielectric spacers 144, the spacers 140, the interposing layer 150, the first semiconductor layers 106, and the mask layer 136 (FIG. 8).

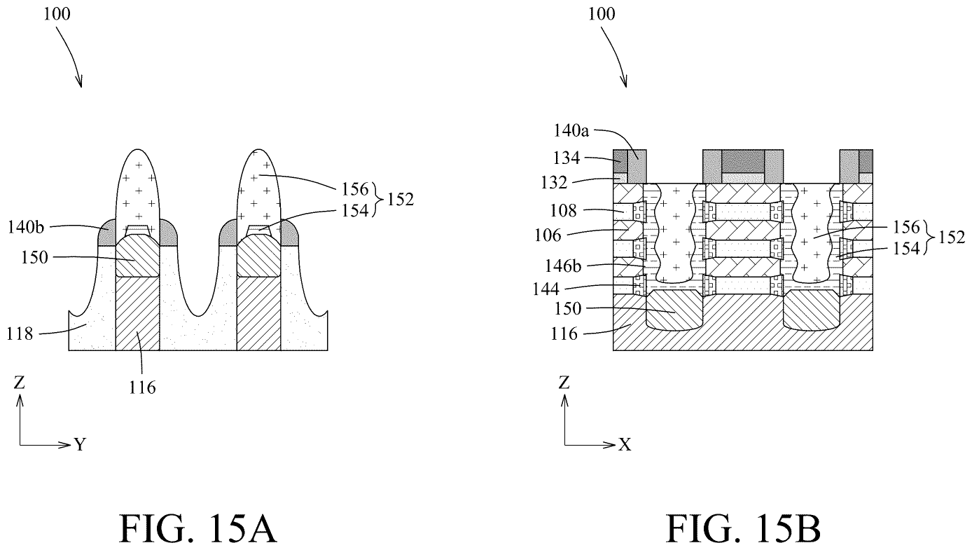

As shown in FIGS. 15A and 15B, a semiconductor layer 154 is formed from the first semiconductor layers 106 and the interposing layer 150, and a semiconductor layer 156 is formed from the semiconductor layer 154. In some embodiments, the semiconductor layer 154 interfacing side surfaces of the first semiconductor layers 106. The semiconductor layers 154, 156 may be made of one or more layers of Si, SiP, SiC, SiAs, SiSb, and SiCP for n-channel FETs or Si, SiGe, Ge, SiGeB for p-channel FETs. For p-channel FETs, p-type dopants, such as boron (B), may be included in the semiconductor layers 154, 156. For n-channel FETs, n-type dopants, such as phosphorus (P) or arsenic (As), may be included in the semiconductor layers 154, 156. In some embodiments, the dopant concentration of the semiconductor layers 154 may range from about 1×10¹⁹ cm⁻³ to about 2×10²¹ cm⁻³. The semiconductor layers 154 may be formed by an epitaxial growth method using CVD, ALD or MBE. As shown in FIG. 15B, in some embodiments, the semiconductor layers 154 is selectively formed on semiconductor materials, such as the first semiconductor layers 106 and the interposing layer 150, and is not formed on dielectric materials, such as the dielectric spacers 144. In some embodiments, the semiconductor layers 154 is a continuous layer that is also formed on the side surfaces of the dielectric spacers 144. In some embodiments, the semiconductor layers 154 and the semiconductor layers 156 may include the same semiconductor materials but with different dopant concentrations. The dopant concentration of the semiconductor layer 156 may be substantially greater than the dopant concentration of the semiconductor layer 154. The semiconductor layer 154 and the semiconductor layer 156 together may be the source/drain (S/D) region 152. In this disclosure, a source region and a drain region are interchangeably used, and the structures thereof are substantially the same. Furthermore, source/drain region(s) may refer to a source or a drain, individually or collectively dependent upon the context. In some embodiments, p-type S/D regions 152 and n-type S/D regions 152 may be formed separately using one or more mask layers. In some embodiments, a thickness of the S/D region 152 along the Z direction is different from a width of the S/D region 152 along the Y direction, as shown in FIG. 15A.

As described above, the portions of the insulating material 118 formed on the side surfaces of the substrate portion 116 are not removed during the high-pressure cyclic etching process and the clean process to remove the oxide layers 146b. If the portions of the insulating material 118 formed on the side surfaces of the substrate portion 116 are removed, the semiconductor layers 154, 156 and the interposing layer 150 may also form from the substrate portion 116. As a result, the adjacent S/D regions 152 may merge by a bridging structure between the adjacent substrate portions 116, which can lead to device failure. In some embodiments, as shown in FIG. 15A, the portion of the insulating material 118 formed on the side surface of the substrate portion 116 has a thickness T along the Y direction. The thickness T may vary due to the shape of the portion of the insulating material 118. In some embodiments, the thickness T ranges from about 6 nm to about 10 nm. If the thickness T is less than about 6 nm, the merging of the adjacent S/D regions 152 may occur. In some embodiments, the thickness T increases is a direction towards the substrate 101. In some embodiments, the thickness of the second portion 140b of the spacer 140 ranges from about 4 nm to about 9 nm.

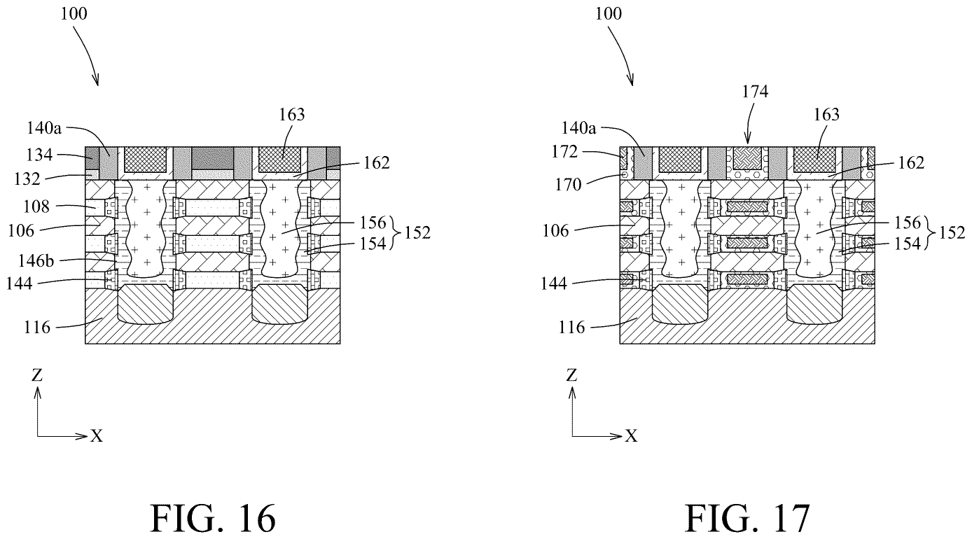

FIGS. 16 and 17 are cross-sectional side views of the semiconductor device structure 100 taken along the line B-B of FIG. 8, in accordance with some embodiments. After forming the S/D regions 152, a contact etch stop layer (CESL) 162 is conformally formed on the exposed surfaces of the semiconductor device structure 100, as shown in FIG. 16. The CESL 162 covers the sidewalls of the first portion 140a of the spacers 140 and is disposed on the second portion 140b of the spacers 140 and the S/D regions 152. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 17. The planarization process may be any suitable process, such as a CMP process. The planarization process removes portions of the ILD layer 163 and the CESL 162 disposed on the sacrificial gate structures 130. The planarization process may also remove the mask layer 136 (FIG. 8).

As shown in FIG. 17, the sacrificial gate electrode layer 134, the sacrificial gate dielectric layer 132, and the second semiconductor layers 108 are removed to expose portions of the first semiconductor layers 106, and a gate dielectric layer 170 and a gate electrode layer 172 are formed to surround the exposed portions of the first semiconductor layers 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 140, the ILD layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 140, the ILD layer 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

As shown in FIG. 17, the gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. The IL may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

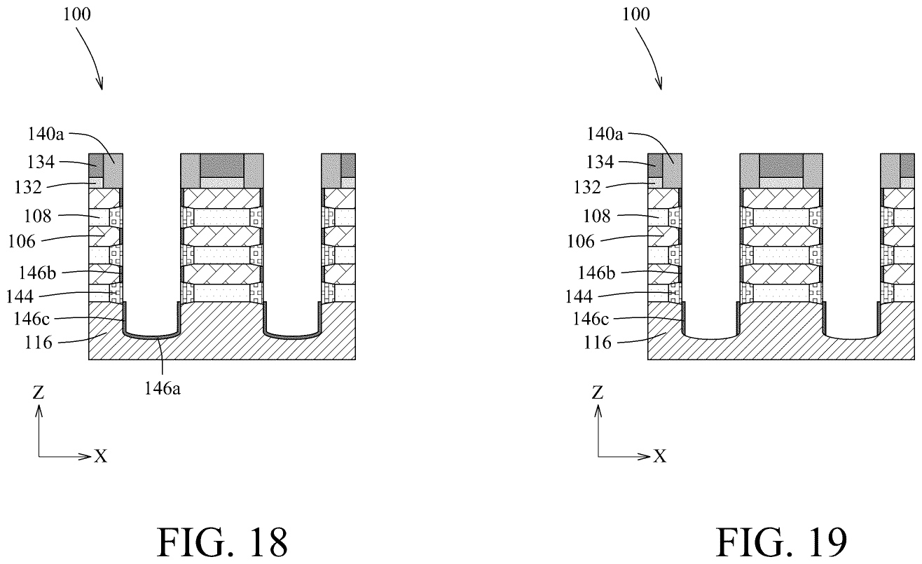

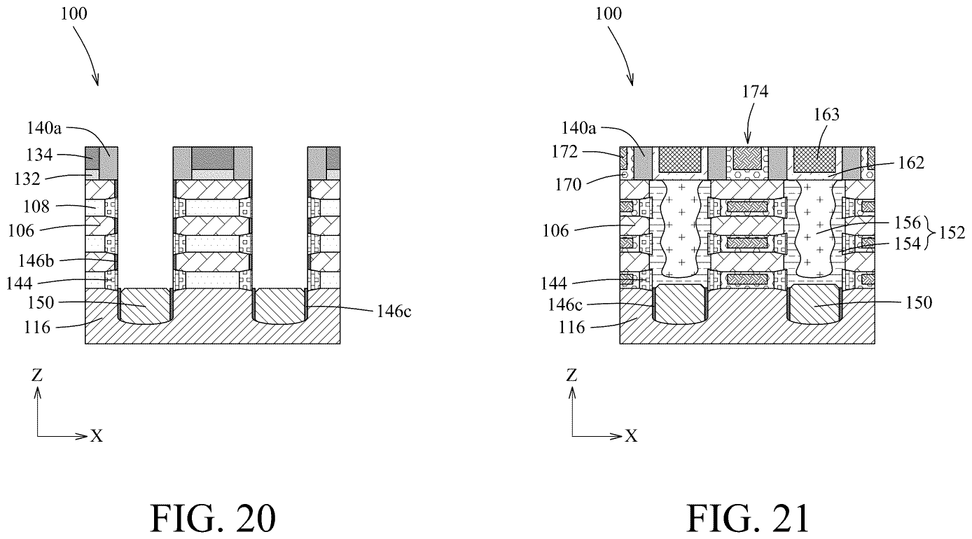

FIGS. 18, 19, and 21 are cross-sectional side views of various stages of manufacturing the semiconductor device structure 100 taken along the line B-B of FIG. 8, in accordance with alternative embodiments. FIG. 18 illustrates the semiconductor device structure 100 at the same manufacturing stage as the semiconductor device structure 100 shown in FIG. 11B. Next, as shown in FIG. 19, the high-pressure cyclic etching process is performed to remove the oxide layers 146a. The oxide layers 146c are not removed due to the anisotropic nature of the high-pressure cyclic etching process. In some embodiments, by reducing the time duration of the cycle or increasing the processing pressure, the oxide layers 146c may remain on the side surfaces of the substrate portions 116. In some embodiments, the oxide layer 146c is located below the dielectric spacer 144, as shown in FIG. 19. The dielectric spacer 144 may protect the oxide layer 146c during the high-pressure cyclic etching process. As shown in FIG. 20, the interposing layer 150 is formed. The interposing layer 150 may be epitaxially grown from the exposed top surface of the substrate portion 116. As described above, the interposing layer 150 can function as an isolation to reduce current leakage. By having the oxide layers 146c, which are dielectric layers, located between the interposing layer 150 and the side surfaces of the substrate portion 116, current leakage is further reduced. Next, as shown in FIG. 21, the S/D regions 152, the CESL 162, the ILD layer 163, and the gate structures 174 are formed.

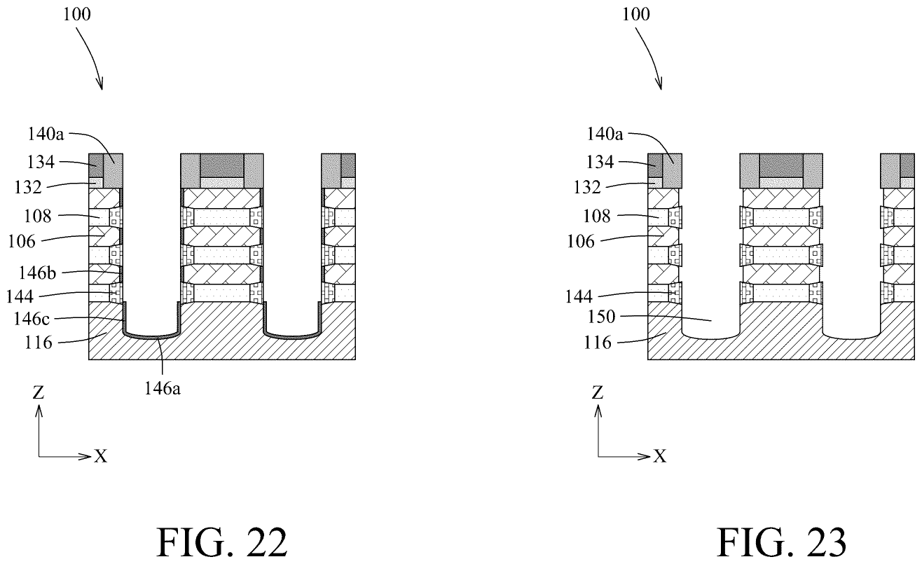

FIGS. 22 and 23 are cross-sectional side views of various stages of manufacturing the semiconductor device structure 100 taken along the line B-B of FIG. 8, in accordance with alternative embodiments. FIG. 22 illustrates the semiconductor device structure 100 at the same manufacturing stage as the semiconductor device structure 100 shown in FIG. 11B. Next, as shown in FIG. 23, the high-pressure cyclic etching process is performed to remove the oxide layers 146a, 146b, and 146c. In some embodiments, by reducing the processing pressure, the high-pressure cyclic etching process is less anisotropic, and the oxide layers 146a, 146b, and 146c may be removed. The reduced processing pressure is still high enough so that the portions of the insulating material 118 formed on the side surfaces of the substrate portions 116 shown in FIG. 12A are not substantially affected.

As described above, the processing pressure of the high-pressure cyclic etching process ranges from about 7 Torr to about 20 Torr. In some embodiments, the processing pressure of the high-pressure cyclic etching process ranges from about 7 Torr to about 11 Torr, and the oxide layers 146a, 146b, 146c are all removed. In some embodiments, the processing pressure of the high-pressure cyclic etching process ranges from about 12 Torr to about 16 Torr, and the oxide layers 146a, 146c are removed, while the oxide layers 146b remain. In some embodiments, the processing pressure of the high-pressure cyclic etching process ranges from about 17 Torr to about 20 Torr, and the oxide layers 146 a are removed, while the oxide layers 146b, 146c remain.

If the oxide layers 146b are removed, the interposing layer 150 may be also formed on the exposed side surfaces of the first semiconductor layers 106. An etch back process may be performed to remove the portions of the interposing layer 150 formed on the side surfaces of the first semiconductor layers 106. Then, the semiconductor layer 154 can be formed from the side surfaces of the first semiconductor layers 106.

Embodiments of the present disclosure provide a method for forming a semiconductor device structure 100. The method includes performing a high-pressure cyclic etching process to remove at least some oxide layers 146a, which are formed as a result of exposure to the atmosphere. Some embodiments may achieve advantages. For example, the high-pressure cyclic etching process is an anisotropic etching process, which does not substantially affect the portions of the insulating material 118 formed on the side surfaces of the substrate portions 116. As a result, merging of adjacent S/D regions 152 is prevented.

An embodiment is a method. The method includes forming a fin structure, and the fin structure includes a first semiconductor layer disposed over a substrate portion. The method further includes removing a portion of the first semiconductor layer to expose a top surface of the substrate portion, a side surface of the substrate portion, and a side surface of the first semiconductor layer, forming a first oxide layer on the exposed top surface of the substrate portion, a second oxide layer on the exposed side surface of the substrate portion, and a third oxide layer on the exposed side surface of the first semiconductor layer, performing a high-pressure cyclic etching process to remove the first oxide layer, and the third oxide layer remains. The method further includes forming a second semiconductor layer on the top surface of the substrate portion and removing the third oxide layer.

Another embodiment is a method. The method includes forming a fin structure, and the fin structure includes a first semiconductor layer disposed over a substrate portion. The method further includes removing a portion of the first semiconductor layer to expose a top surface of the substrate portion, a side surface of the substrate portion, and a side surface of the first semiconductor, forming a first oxide layer on the exposed top surface of the substrate portion, a second oxide layer on the exposed side surface of the substrate portion, and a third oxide layer on the exposed side surface of the first semiconductor layer, performing a high-pressure cyclic etching process to remove the first oxide layer, and the second oxide layer remains. The method further includes forming a second semiconductor layer on the top surface of the substrate portion, and the second oxide layer is between the second semiconductor layer and the side surface of the substrate portion.

A further embodiment is a semiconductor device structure. The structure includes a source/drain region having a first semiconductor layer and a second semiconductor layer, the first semiconductor layer and the second semiconductor layer are doped with a dopant, a concentration of the dopant in the first semiconductor layer is different from a concentration of the dopant in the second semiconductor layer, and a thickness of the source/drain region is different from a width of the source/drain region in a cross-sectional view. The structure further includes a third semiconductor layer disposed below the source/drain region, a fourth semiconductor layer interfacing a side surface of the first semiconductor layer, a substrate portion disposed below the fourth semiconductor layer, an oxide layer disposed between the substrate portion and the third semiconductor layer, a contact etch stop layer disposed over the source/drain region, and an interlayer dielectric (ILD) layer disposed over the contact etch stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure, wherein the fin structure comprises a first semiconductor layer disposed over a substrate portion;
removing a portion of the first semiconductor layer to expose a top surface of the substrate portion, a side surface of the substrate portion, and a side surface of the first semiconductor layer;
forming a first oxide layer on the exposed top surface of the substrate portion, a second oxide layer on the exposed side surface of the substrate portion, and a third oxide layer on the exposed side surface of the first semiconductor layer;
performing a high-pressure cyclic etching process to remove the first oxide layer, wherein the third oxide layer remains;
forming a second semiconductor layer on the top surface of the substrate portion; and
removing the third oxide layer.

2. The method of claim 1, wherein the high-pressure cyclic etching process has a processing pressure ranging from about 7 Torr to about 20 Torr.

3. The method of claim 1, wherein the high-pressure cyclic etching process comprises repeating a cycle, and the cycle comprises an etchant generating stage, an etching stage, and a sublimation stage.

4. The method of claim 3, wherein the etchant generating stage has a first processing temperature, and the sublimation stage has a second processing temperature greater than the first processing temperature.

5. The method of claim 3, wherein a time duration of the cycle ranges from about 20 seconds to about 30 seconds.

6. The method of claim 1, wherein the first, second, and third oxide layers are formed by exposing the top surface of the substrate portion, the side surface of the substrate portion, and the side surface of the first semiconductor layer to an atmosphere.

7. The method of claim 1, wherein the fin structure further comprises a second semiconductor layer disposed over the first semiconductor layer.

8. A method, comprising:
forming a fin structure, wherein the fin structure comprises a first semiconductor layer disposed over a substrate portion;
removing a portion of the first semiconductor layer to expose a top surface of the substrate portion, a side surface of the substrate portion, and a side surface of the first semiconductor;
forming a first oxide layer on the exposed top surface of the substrate portion, a second oxide layer on the exposed side surface of the substrate portion, and a third oxide layer on the exposed side surface of the first semiconductor layer;
performing a high-pressure cyclic etching process to remove the first oxide layer, wherein the second oxide layer remains; and
forming a second semiconductor layer on the top surface of the substrate portion, wherein the second oxide layer is between the second semiconductor layer and the side surface of the substrate portion.

9. The method of claim 8, further comprising removing the second oxide layer by a clean process.

10. The method of claim 9, wherein the clean process has a process pressure lower than a processing pressure of the high-pressure cyclic etching process.

11. The method of claim 9, wherein the clean process is performed after the forming of the second semiconductor layer.

12. The method of claim 9, further comprising forming a third semiconductor layer over the second semiconductor layer and adjacent the first semiconductor layer.

13. The method of claim 12, further comprising forming a fourth semiconductor layer on the third semiconductor layer.

14. The method of claim 8, wherein the high-pressure cyclic etching process has a processing pressure ranging from about 7 Torr to about 20 Torr.

15. The method of claim 8, wherein the high-pressure cyclic etching process comprises repeating a cycle, and the cycle comprises an etchant generating stage, an etching stage, and a sublimation stage.

16. A semiconductor device structure, comprising:
a source/drain region comprising a first semiconductor layer and a second semiconductor layer, wherein the first semiconductor layer and the second semiconductor layer are doped with a dopant, a concentration of the dopant in the first semiconductor layer is different from a concentration of the dopant in the second semiconductor layer, and a thickness of the source/drain region is different from a width of the source/drain region in a cross-sectional view;
a third semiconductor layer disposed below the source/drain region;
a fourth semiconductor layer interfacing a side surface of the first semiconductor layer;
a substrate portion disposed below the fourth semiconductor layer;
an oxide layer disposed between the substrate portion and the third semiconductor layer;
a contact etch stop layer disposed over the source/drain region; and
an interlayer dielectric (ILD) layer disposed over the contact etch stop layer.

17. The semiconductor device structure of claim 16, further comprising a gate structure disposed between the substrate portion and the fourth semiconductor layer.

18. The semiconductor device structure of claim 17, further comprising a dielectric spacer disposed between the gate structure and the first semiconductor layer.

19. The semiconductor device structure of claim 18, wherein the dielectric spacer is disposed on the oxide layer.

20. The semiconductor device structure of claim 16, wherein the oxide layer comprises silicon oxide.
